(19) United States
(12) Patent Application Publication
(10) Pub. No.: US 2026/0116745 A1
(43) Pub. Date: Apr. 30, 2026

(54) DEEP TRENCHES ON MICROELECTROMECHANICAL SYSTEM WAFERS FOR STEALTH DICING

(71) Applicant: Lumentum Operations LLC, San Jose, CA (US)

(72) Inventors: Edward WANG, Ottawa (CA); Wenlin JIN, Ottawa (CA); John Michael MILLER, Ottawa (CA); Parsoua ABEDINI SOHI, Nepean (CA); Jino FATHY, Ottawa (CA); Chi-li-ma HARNOLD, Sugar Land, TX (US)

(21) Appl. No.: 19/087,896

(22) Filed: Mar. 24, 2025

Related U.S. Application Data
(60) Provisional application No. 63/696,955, filed on Sep. 20, 2024.

(51) Int. Cl. B81C 1/00; B81B 3/00; G02B 26/08

(52) U.S. Cl. CPC B81C 1/00873; G02B 26/0833; B81B 3/0018; B81B 2201/042

(57) ABSTRACT

A die includes a substrate; an insulation layer arranged on the substrate; a device layer arranged on the insulation layer, with a microelectromechanical systems (MEMS) device, having openings into one or more inner cavities, being defined within the device layer; a shelf, around an outside of the die, that delineates a change in a cross-sectional width of the die; and weakened structural regions arranged below the shelf and proximate to the outside of the die. The shelf is arranged at a predefined depth of the die such that the shelf is arranged at the device layer, at the insulation layer, or at the substrate.

### CROSS-REFERENCE TO RELATED APPLICATION

This Patent application claims priority to U.S. Provisional Patent Application No. 63/696,955, filed on Sep. 20, 2024, and entitled “DEEP TRENCHES ON MICROELECTROMECHANICAL SYSTEM WAFERS FOR STEALTH DICING.” The disclosure of the prior Application is considered part of and is incorporated by reference into this Patent Application.

### TECHNICAL FIELD

The present disclosure relates generally to optical microelectromechanical systems (MEMS) dies and to methods of manufacturing optical MEMS dies.

### BACKGROUND

Singulation is a process in semiconductor manufacturing where a wafer, containing numerous individual circuits or dies, is divided into individual units for use in electronic devices. Each individual unit may correspond to a respective die. An objective of singulation is to separate the dies with precision, while minimizing damage to each die. Given the precision required, singulation is carefully controlled to avoid damage or contamination, which could impact device performance.

### SUMMARY

In some implementations, a die includes a substrate; an insulation layer arranged on the substrate; a device layer arranged on the insulation layer, wherein a microelectromechanical systems (MEMS) device, having openings into one or more inner cavities, is defined within the device layer; a shelf arranged around an outside of the die, wherein the shelf delineates a change in a cross-sectional width of the die, and wherein the shelf is arranged at a predefined depth of the die, the shelf being arranged at the device layer, at the insulation layer, or at the substrate; and weakened structural regions arranged below the shelf and proximate to the outside of the die.

In some implementations, a wafer includes a substrate; an insulation layer arranged on the substrate; a plurality of device layers arranged on the insulation layer, the plurality of device layers including an upper device layer; trenches extending into the wafer from the upper device layer and delineating a set of dies in the wafer, the trenches having trench bottoms; and regions, arranged below the bottoms of the trenches, comprising aligned structural weaknesses, wherein each die of the set of dies having an optical MEMS surface in the upper device layer and one or more inner cavities below the optical MEMS surface.

In some implementations, a method of manufacturing a plurality of optical MEMS dies includes forming an unreleased wafer assembly including a wafer substrate, an insulation layer formed on the wafer substrate, and a plurality of device layers formed on the insulation layer, wherein the plurality of device layers includes an upper device layer and one or more inner cavities, wherein the one or more inner cavities contain MEMS actuation structures that are sensitive to particulate, and wherein the upper device layer of the plurality of device layers is sealed such that the one or more inner cavities are closed; after forming the unreleased wafer assembly and before opening the one or more inner cavities, forming deep trenches along singulation lanes that delineate the optical MEMS dies in the unreleased wafer assembly, wherein each deep trench extends from the upper device layer to a depth that is at least partially into the plurality of device layers; after forming deep trenches, forming a released wafer assembly by unsealing the upper device layer thereby opening the one or more inner cavities of the unreleased wafer assembly to form a plurality of optical MEMS devices in the plurality of device layers; after forming the released wafer assembly, emitting one or more laser beams into the wafer substrate to create defect regions within the singulation lanes of the wafer substrate; and after emitting the one or more laser beams, separating the released wafer assembly, through the defect regions in the wafer substrate, into the plurality of optical MEMS dies.

### BRIEF DESCRIPTION OF THE DRAWINGS

FIGS. 1A-1F are diagrams of examples associated with a method of manufacturing a plurality of optical MEMS dies.

FIG. 2 shows a cross-section of an optical MEMS die according to one or more implementations.

FIG. 3 is a flowchart of an example process associated with forming deep trenches on microelectromechanical system wafers for stealth dicing.

### DETAILED DESCRIPTION

The following detailed description of example implementations refers to the accompanying drawings. The same reference numbers in different drawings may identify the same or similar elements.

Semiconductor processing technologies may be used to manufacture MEMS dies. Multiple MEMS dies may be formed on a wafer and then singulated into separate MEMS dies during a singulation process. A MEMS die may include one or more MEMS devices, whose internal MEMS device structures are sensitive to particulates, such as micro particles, and contaminants. For example, an optical MEMS die may include one or more optical MEMS devices, such as one or more MEMS mirror devices. Each MEMS mirror device may include an optical structure (e.g., including a reflective layer or mirror) configured to rotate or pivot about one or more axes, and actuation structures configured to actuate a movement of the optical structure about the one or more axes. An operation of each of the actuation structures is extremely sensitive to particulates and contaminants, which can cause errors in actuating the optical structure and/or errors in a rotational position of the optical structure about the one or more axes. Therefore, exposing the internal MEMS device structures to particulates and contaminants during manufacturing can negatively impact a yield of a number of MEMS dies produced. Thus, it is important to protect the internal MEMS device structures from exposure to particulates and contaminants during manufacturing.

Traditional dicing techniques, such as saw-based dicing scribing and breaking, etching (e.g., deep reactive ion etching) and laser ablation, may be used for singulating (e.g., separating) MEMS dies. However, traditional dicing techniques generate a lot of particulates, which deposit on or near one or more surfaces of a MEMS die. The particulates may also enter one or more inner cavities of the MEMS die, and may interfere with the internal MEMS device structures, such as actuation structures that actuate movement of the optical structure about the one or more axes. This is particularly problematic where the entrances to the inner cavities of a MEMS die are proximate to the singulation lanes. For example, non-conductive particulates or contaminants having a size close to or larger than the internal MEMS device structures would have a severe impact to MEMS functions and performance in comparison to non-conductive particulates smaller than the than the internal MEMS device structures. In comparison to non-conductive particulates or contaminants, conductive particulates or contaminants can be even more detrimental to the MEMS functions and the performance than non-conductive particulates and contaminants. Since most of MEMS finest structures are sized at the micron or the submicron level, particulates or contaminants at the submicron size level or smaller have to be prevented from entering the inner cavities, where they can make contact with the internal MEMS device structures and negatively impact the operation of the MEMS device.

Stealth dicing has been used in the semiconductor industry to singulate individual die from a wafer assembly, typically made of materials like silicon. Stealth dicing employs a laser to create internal modifications within the wafer assembly, along singulation lanes, without cutting through the wafer assembly. The internal modifications form weakened structural regions. In other words, stealth dicing uses a laser to create a modified layer within the wafer assembly beneath a surface of the wafer assembly, along the singulation lanes. The modified layer may comprise weakened structural regions. After a laser process creates the internal modifications the wafer assembly undergoes a mechanical separation process, which may include using a tape expander, stretching tape that is attached to the wafer assembly, or the like. During the mechanical separation process, the wafer assembly is stretched or stressed, causing micro-cracks to propagate and split the wafer assembly along the singulation lanes through or near the modified layer or weakened structural regions and resulting in the individual dies being separated.

While stealth dicing does not generate particulate or other contaminants when creating internal modifications, the mechanical separation of die later in the stealth dicing process does generate particulates that increases the risk of particulate contamination for the internal MEMS device structures. While the amount of particulate contamination from stealth dicing is considerably less than traditional dicing techniques (e.g., saw-based dicing, scribing and breaking, etching, deep reactive ion etching, or laser ablation), the amount of particulate is still a significant problem for highly particulate-sensitivity MEMS die. For example, a yield of MEMS die manufactured with semiconductor processes is extremely sensitive to conductive particulates that may be generated during mechanical separation by low-resistivity top device layers of the wafer assembly.

Manufacturing techniques that reduce an amount of particulate generated during singulation (e.g., wafer-separation particulate) may reduce a likelihood of particulate contamination. Additionally, manufacturing techniques that protect the internal MEMS device structures from exposure to particulates can also reduce a likelihood of particulate contamination. Thus, manufacturing techniques that reduce the amount of particulate generated during singulation, especially conductive particulates from the low-resistivity top device layers, and/or that better protect the internal MEMS device structures from the particulates are desired.

Some implementations disclosed herein are directed to die, wafers, and manufacturing techniques that reduce an amount of particulate on or within a MEMS device in the die or wafer. For example, some implementations are directed to a die that includes a substrate, an insulation layer arranged on the substrate, and one or more device layers arranged on the insulation layer. The die includes a MEMS device, such as an optical MEMS device, defined within the one or more device layers device layers. The MEMS device includes openings into one or more inner cavities defined by the device layers. Additionally, the MEMS device includes internal MEMS device structures, such as actuation structures actuation structures or other electrical drive mechanisms, arranged in the one or more inner cavities that are sensitive to particulate contamination. The one or more inner cavities may be devoid of particulates. Thus, the MEMS device may be free of particulate contamination, which improves an operation of the MEMS device. The die may be manufactured by manufacturing process described elsewhere herein that prevent particulate from entering the one or more inner cavities.

The die also includes a shelf that extends around an outside of the die. The shelf delineates a change in a cross-sectional width of the die. For example, above the shelf, the die may have a first cross-sectional width, and, below the shelf, the die may have a second cross-sectional width that is larger than the first cross-sectional width. The shelf is arranged at a predefined depth of the die, where the predefined depth is defined by an extension from a top surface of the die (e.g., a top surface of the one or more device layers) toward a bottom surface of the die (e.g., a bottom surface of the substrate). For example, the shelf is arranged at a device layer of the one or more device layers, at the insulation layer, or at the substrate. In some examples, the shelf is a bottom of a trench.

In some examples, the shelf is arranged at an upper surface of the substrate or within the substrate. The substrate may be made of a homogeneous crystalline semiconductor material that has a surface capable of being conditioned or otherwise processed for high optical smoothness and to be horizontal. The shelf may be arranged at the surface of the substrate that has been processed for high optical smoothness. In other words, the shelf formed at the substrate is an optically smooth surface configured to reduce optical scattering of a laser beam. For example, the shelf may receive the laser beam at the optically smooth surface, and the optically smooth surface may enable the laser beam to pass through the shelf and into the substrate while limiting optical scattering and back reflection of the laser beam. As a result of limiting optical scattering and back reflection of the laser beam, the shelf enables the laser beam to enter the substrate at a desired direction, depth, and optical power. The die may be manufactured by manufacturing process described elsewhere herein.

Some implementations are directed to a wafer that includes a substrate, an insulation layer arranged on the substrate; and a plurality of device layers arranged on the insulation layer. The wafer also includes trenches, extending into the wafer from an upper device layer of the plurality of device layers, delineating a set of dies in the wafer. In other words, the trenches may be formed along singulation lanes at which the set of dies are separated during a mechanical die separation process. The trenches have trench bottoms located at a predefined depth within the wafer. Each die has an optical MEMS surface in the upper device layer and one or more inner cavities below the optical MEMS surface. Additionally, each die includes internal MEMS device structures, such as actuation structures, that are arranged in at least one of the inner cavities and are sensitive to particulate contamination.

The inner cavities of the wafer may be devoid of particulates. For example, the trenches are configured to trap particulates originating from the substrate and/or the device layers such that the particulates do not land on the upper surface or enter the inner cavities of the wafer. The trenches are dimensioned such that the particulates are trapped within the trenches and do not exit the trenches in a way that they can land on the upper surface or enter the inner cavities of the wafer.

In some implementations, the trenches extend to the substrate such that the device layers and the insulation layer are removed at singulation lanes to form the trenches. In other words, the trench bottoms are located at the substrate, which presents some advantages.

First, removing the device layers and the insulation layer to form the trenches prevents those layers, which are absent during the mechanical die separation process due to removal, from generating particulates during the mechanical die separation process. Thus, having the trench bottoms at the substrate, an amount of wafer-separation particulate generated during the mechanical die separation process can be reduced. Reducing the amount of wafer-separation particulate generated during the mechanical die separation process may reduce a likelihood of particulate contamination at the die, and particularly within the inner cavities of the wafer. As a result, a yield of operable die may be increased.

Second, the device layers may have very low resistivity (e.g., as low as 0.02 Ω·cm). Thus, if the device layers are present in the singulation lanes during the mechanical die separation process, the device layers could generate conductive particulate. By removing the device layers from the singulation lanes by forming the trenches, conductive particulate from the device layers are not generated during the mechanical die separation process, which serves in reducing an amount of conductive particulate (and total particulate) generated during the mechanical die separation process. In some cases, generating conductive particulate during the mechanical die separation process may be prevented. Reducing the amount of conductive particulate (and total particulate) generated during the mechanical die separation process may reduce a likelihood of particulate contamination at the die, and particularly within the inner cavities of the wafer. As a result, a yield of operable die may be increased.

Third, having the trench bottoms at the substrate may enable the trench bottoms (e.g., a surface of the substrate defining the trench bottoms) to be conditioned or otherwise processed for high optical smoothness and to be horizontal. The substrate is made of a homogeneous crystalline semiconductor material that has a surface capable of being conditioned for high optical smoothness. Thus, the trench bottoms formed at the substrate may be optically smooth surfaces configured to reduce optical scattering of one or more laser beams emitting during stealth dicing. For example, a trench bottom, being an optically smooth surface may receive laser beams, and the trench bottom may enable the laser beams to pass through the trench bottom and into the substrate while limiting optical scattering and back reflection of the laser beams. As a result of limiting optical scattering and back reflection of the laser beams, the trench bottom enables each laser beam to enter the substrate at a desired direction, depth, and optical power.

Laser beams may be emitted into the substrate during stealth dicing to create defect regions (e.g., weakened structural regions) in the substrate, the defect regions being aligned with the singulation lanes. The defect regions may be formed at different depths within the substrate. In order to provide a clean, smooth, and precise separation of the dies during the mechanical die separation process, the defect regions should be vertically aligned and formed at optimized depths. Misalignment of the defect regions and/or forming the defect regions at unoptimized depths (e.g., too close together or too far apart) may cause cracking, breaking, and/or chipping at edges of the dies from the mechanical die separation process. In some cases, misalignment of the defect regions can lead to a lower yield of dies due to the cracking, breaking, and/or chipping.

As noted above, the trench bottoms may be optically smooth and horizontal to limit optical scattering and back reflection of the laser beams such that laser beams are emitted into the substrate at a desired direction, depth, and optical power. As a result, the trench bottoms may ensure that the defect regions are vertically aligned and are formed at intended depths with the intended optical power, which enables a cleaner, smoother, more precise separation during the wafer separation process. As a result, edges of the substrate (e.g., edges of the dies) after the mechanical die separation process are straight and smooth. Moreover, a likelihood of cracking, breaking, and/or chipping at the edges of substrate (e.g., edges of the dies) is reduced, thereby increasing a yield of operable die. The wafer may be manufactured by manufacturing process described elsewhere herein.

Thus, some implementations may be directed to reducing an amount of particulate accumulating on a MEMS wafer and/or on MEMS dies, and reducing an amount of particulate entering one or more inner cavities of the MEMS wafer and/or MEMS dies where the particulate can interfere with internal MEMS device structures. As a result, reliability of each MEMS die may be improved. In addition, a yield of MEMS dies produced from a wafer is improved. In some implementations, manufacturing techniques used to produce the die or the wafer may incorporate aspects of both traditional dicing and stealth dicing processes.

Some implementations are directed to a method of manufacturing a plurality of optical MEMS dies. The method of manufacturing may be used to produce the aforementioned wafer and die. The method may include forming an unreleased wafer assembly, with an upper layer (of the unreleased wafer assembly being sealed such that inner cavities of the unreleased wafer assembly are closed. Forming the unreleased wafer assembly may include arranging an insulation layer on a substrate (e.g., a homogeneous crystalline semiconductor substrate), and arranging a plurality of device layers (e.g., silicon layers) on the insulation layer. The plurality of device layers may be processed to define the inner cavities in which internal MEMS device structures, such as actuation structures, are arranged. The upper layer is an upper device layer of the plurality of device layers. As a result of the upper layer of the unreleased wafer assembly being sealed, the internal MEMS device structures arranged within the inner cavities of the unreleased wafer assembly are protected from particulates and other contaminants.

After forming the unreleased wafer assembly and before opening the inner cavities, the method may further include forming deep trenches along singulation lanes that delineate optical MEMS dies in the unreleased wafer assembly. Forming the deep trenches may ultimately reduce an amount of wafer-separation particulate generated during a separation process step (e.g., a mechanical die separation process), as discussed above. Additionally, the deep trenches may function as particle traps during the separation process step to prevent particulate from spreading over the upper layer and/or entering the inner cavities. The deep trenches are dimensioned such that the particles are trapped within the deep trenches. For example, the deep trenches have a depth-to-width ratio that is sufficient to trap particulate and to prevent particulate from spreading over the upper layer where it could enter the inner cavities. In addition, the deep trenches are wider that a stealth dicing laser beam width to ensure that the device layers do not interfere with the laser beams emitted during stealth dicing. The deep trenches may be formed around a periphery of each of the MEMS dies to ensure particles are trapped at all sides of the MEMS dies.

After forming the deep trenches, the method may further include forming a released wafer assembly by unsealing the upper layer, thereby opening the inner cavities of the unreleased wafer assembly to form a plurality of optical MEMS devices in the released wafer assembly. Unsealing the upper layer releases the plurality of optical MEMS devices from the upper layer, which enables a functionality of the plurality of optical MEMS devices. For example, releasing the plurality of optical MEMS devices from the upper layer may enable the plurality of optical MEMS devices to rotate or pivot about one or more axes. However, releasing the plurality of optical MEMS devices from the upper layer also opens the inner cavities exposing them to contamination risks, such as from particulate generated in subsequent processing steps (e.g., the separation process step). Cleaning the optical MEMS devices after opening (releasing) the inner cavities is generally not recommended. For example, during such cleaning the inner cavities could be contaminated, or the released optical MEMS devices could be damaged. If cleaning was performed after opening the inner cavities, particulate on the upper surface could be displaced during cleaning and enter into an inner cavity where it could come into contact with an internal MEMS device structure. Moreover, cleaning within the inner cavities to remove particulate from the inner cavities is typically not possible. For example, the inner cavities are very difficult to access for cleaning. Additionally, the internal MEMS device structures are incredibly fragile and could be easily damaged by applying a cleaning process within the inner cavities.

After forming the released wafer assembly, the method may further include emitting one or more laser beams into a wafer substrate of the released wafer assembly to create defect regions within the singulation lanes of the wafer substrate. In some implementations, emitting one or more laser beams may be part of a stealth dicing process. After emitting the one or more laser beams, the method may further include the separation process step, which includes separating the released wafer assembly, through the defect regions in the wafer substrate, into the optical MEMS dies.

The deep trenches function to reduce the amount of particulate generated by the released wafer assembly during the separation process step. For example, by forming the deep trenches through the device layers, particulate generated by the device layers during the separation process step can be reduced or prevented. This is particularly important due to the device layers being made of a material that has a very low resistivity and could generate conductive particulate during the separation process step. Thus, forming the deep trenches through the device layers reduces an amount of conductive particulate generated during the separation process step and reduces a likelihood of conductive particulate entering the inner cavities where it can come into contact with the internal MEMS device structures, such as actuation structures or other electrical drive mechanisms.

In addition, the deep trenches function as particle traps to prevent particulates from spreading to an upper surface of the optical MEMS dies and/or entering the inner cavities where the internal MEMS device structures reside. Thus, the deep trenches protect the upper surface and the inner cavities of the optical MEMS dies from particulates (e.g., by significantly reducing chances that particulate from the separation process step will exit the deep trenches).

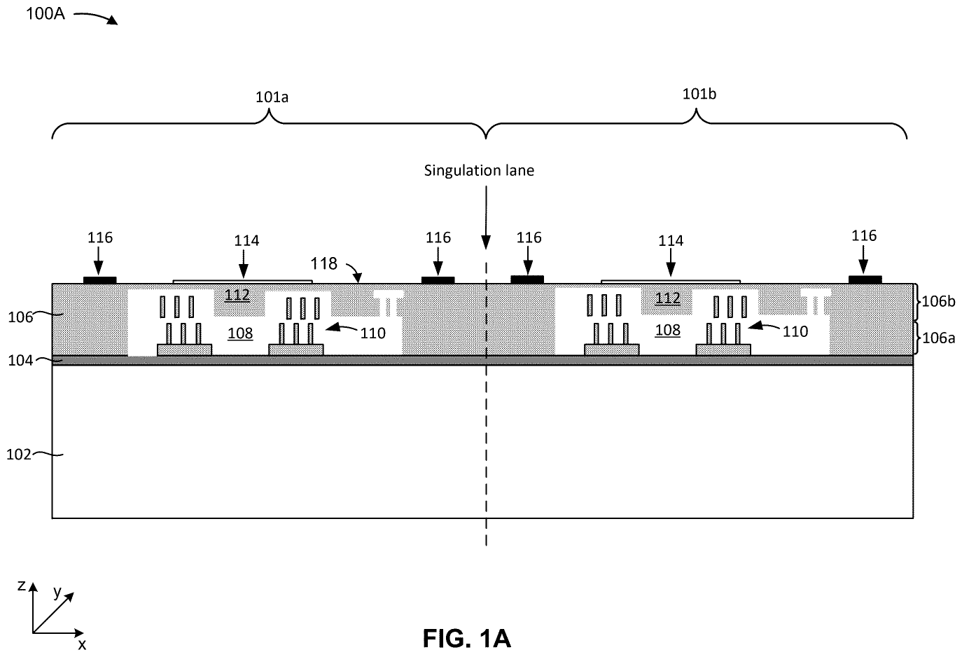

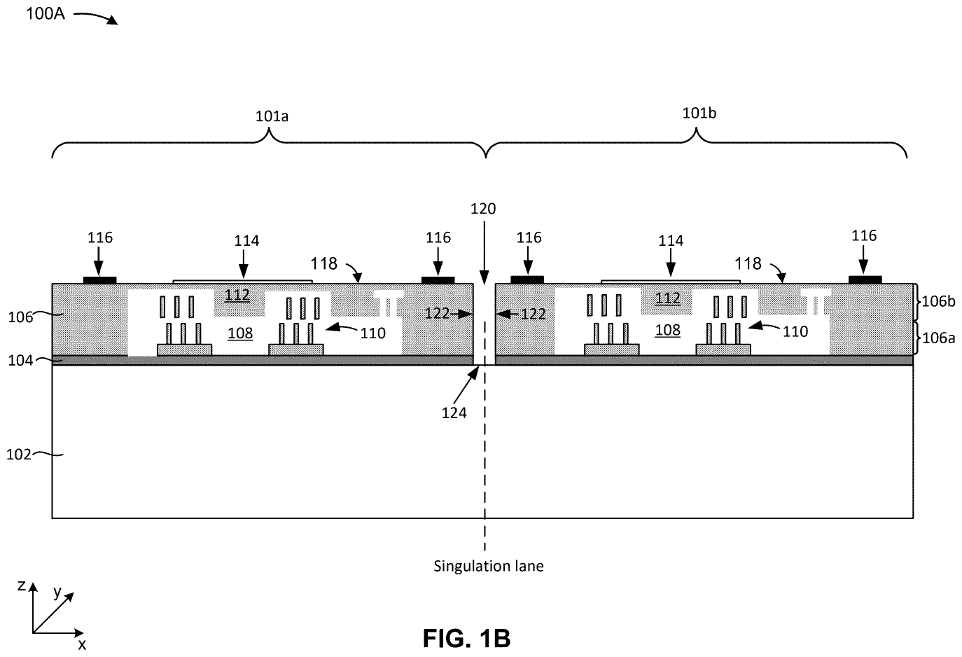

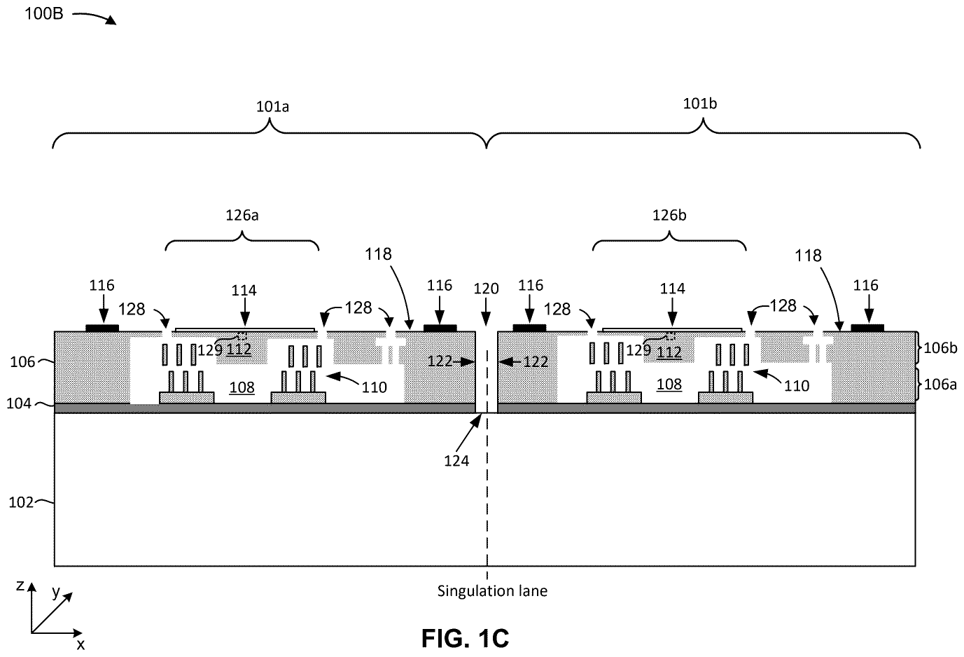

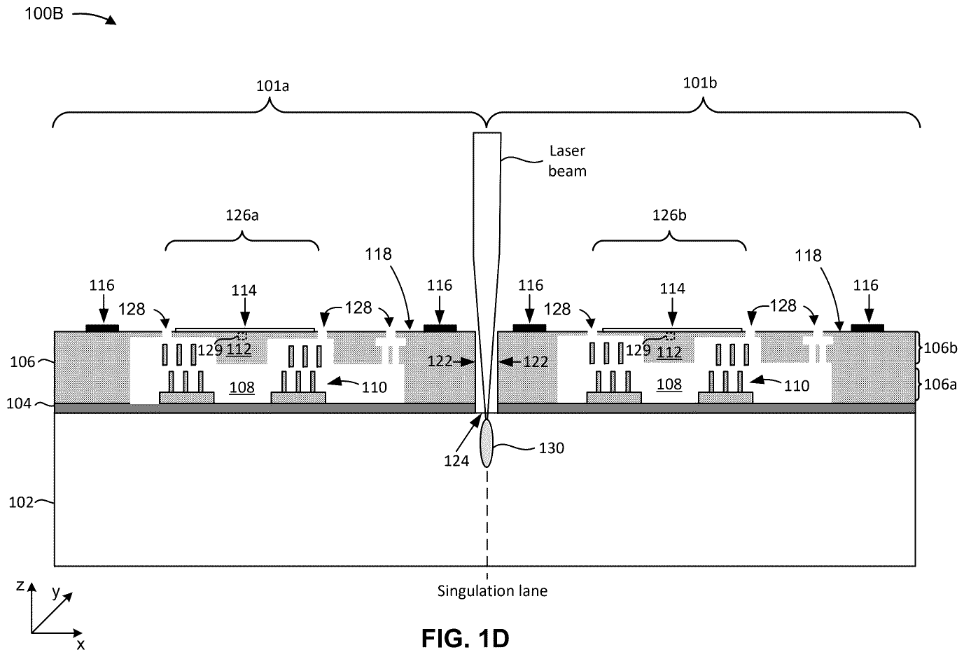

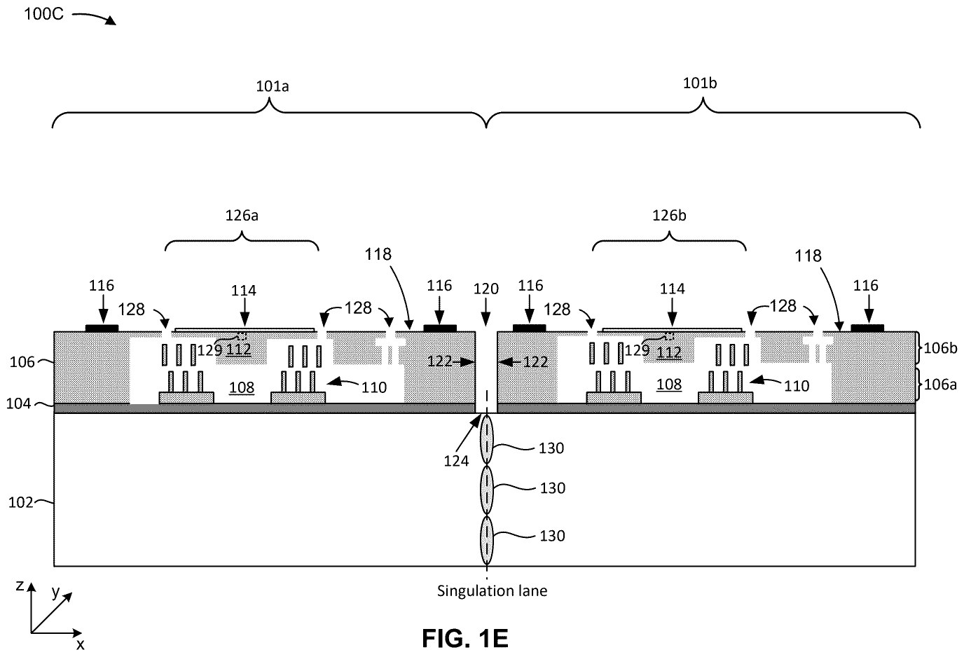

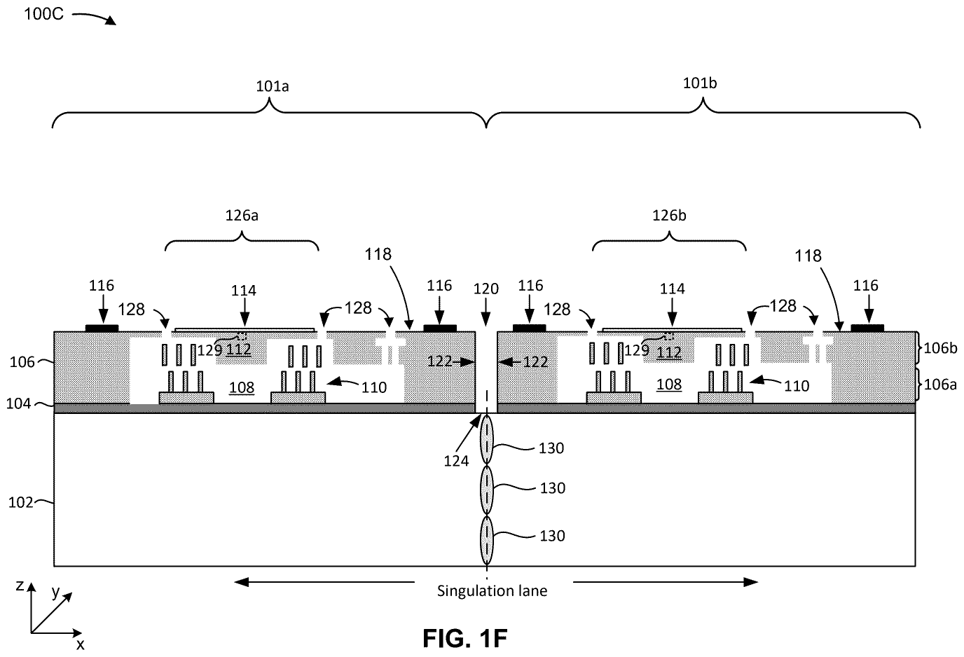

FIGS. 1A-1F are diagrams of examples associated with a method of manufacturing a plurality of optical MEMS dies.

As shown in FIG. 1A, an unreleased wafer assembly 100A may be provided. However, the method of manufacturing may include forming the unreleased wafer assembly 100A, as described above. One or more singulation lanes may delineate optical MEMS dies 101a and 101b in the unreleased wafer assembly 100A. While only two optical MEMS dies are shown in FIGS. 1A-1F, the unreleased wafer assembly 100A may include three or more optical MEMS dies to be singulated into separate optical MEMS dies by a separation process step. In addition, while only one singulation lane is shown in FIGS. 1A-1F, a plurality of singulation lanes may be used for singulating the plurality of optical MEMS dies. For example, perimeters of the optical MEMS dies 101a and 101b may be encircled by singulation lanes.

The unreleased wafer assembly 100A may include a wafer substrate 102, an insulation layer 104 (e.g., multiple insulation layers 104) formed on the wafer substrate 102, and a plurality of device layers 106 formed on the insulation layer 104. The wafer substrate 102 may be made of a homogeneous crystalline semiconductor material, such as silicon. In some examples, the insulation layer 104 may be a silicon dioxide layer. In some cases, the insulation layer 104 may be a buried oxide layer. The plurality of device layers 106 may include semiconductor layers, such as silicon layers, that have low resistivity (e.g., as low as 0.02 Ω·cm). In some embodiments, the unreleased wafer assembly 100A may be a silicon on insulator (SOI) wafer.

The plurality of device layers 106 may include at least two device layers arranged in a device layer stack. For example, the plurality of device layers 106 may include a lower device layer 106a and an upper device layer 106b made of a semiconductor material. The plurality of device layers 106 may be formed, for example, by etching. The device layers 106 contain features of MEMS devices. When in the condition of the unreleased wafer assembly 100A, some of those features are completely formed and some are not. For example, in the unreleased wafer assembly 100A, the plurality of device layers 106 include inner cavities 108 and internal MEMS device structures 110. The internal MEMS device structures 110 may include actuation structures or other electrical drive mechanisms used for operating respective optical MEMS devices of the optical MEMS dies 101a and 101b. In addition, the plurality of device layers 106 of the unreleased wafer assembly 100A may be formed to partially define portions MEMS mirror bodies 112 of respective optical MEMS devices. Each MEMS mirror body 112 may be arranged over a respective inner cavity 108. A peripheral portion of the upper device layer 106b, for each optical MEMS die 101 may serve as a frame 113 that is rotationally fixed. Thus, each MEMS mirror body 112 is attached to a respective frame 113.

The upper device layer 106b of the unreleased wafer assembly 100A may be sealed such that the inner cavities 108 are closed (e.g., not exposed to particulate contamination), thereby preventing particulates from entering the inner cavities 108 and protecting the internal MEMS device structures 110 from the particulates.

The internal MEMS device structures 110 include actuation structures or other electrical drive mechanisms used to drive the MEMS mirror body 112 about one or more axes. In some examples, actuation structures may include interdigitated finger electrodes made of interdigitated mirror combs and frame combs to which a drive voltage, current, or other electrical signal (e.g., an actuation signal or driving signal) is applied. In some embodiments, applying a difference in electrical potential between interleaved mirror combs and frame combs creates a driving force between the mirror combs and the frame combs, which creates a torque on the MEMS mirror body 112 about an intended axis and causes the MEMS mirror body 112 to rotate. In some implementations, other actuation methods, such as electromagnetic actuation, piezoelectric actuation, or thermal actuation, may be used.

As described above, the internal MEMS device structures 110, including actuation structures, are extremely sensitive to particulate contamination. Conductive particulate from the device layers 106 can be especially harmful to an operation of the internal MEMS device structures 110. For example, in some examples, particulates may cause electrical shorts or other electrical impairments at the internal MEMS device structures 110, including at the actuation structures and/or at drive signal traces that interfere with an electrical operation of the actuation structures. Particulates that come in contact with the actuation structures can cause errors in actuating the MEMS mirror body 112 and/or errors in a rotational position of the MEMS mirror body 112 about the one or more axes of rotation. In some examples, the particulates may interfere with the movement of the actuation structures and/or cause damage to the actuation structures.

Optical surfaces 114 and bond pads 116 may be formed on an upper surface 118 of the upper device layer 106b. The optical surfaces 114 may be made of aluminum (Al), gold (Au), Silver (Ag), Copper (Cu), or another type of material suitable for reflective light. Each optical surface 114 may be formed on a respective MEMS mirror body 112. Thus, each optical surface 114 may be a reflective surface or a mirror surface used to receive and steer light during operation.

Bond pads 116 are formed on the frame 113 of each optical MEMS dies 101. The bond pads 116 may be made of aluminum (Al), gold (Au), Silver (Ag), Copper (Cu), or another type of material suitable for conducting electrical signals. In some implementations, the optical surfaces 114 and the bond pads 116 may be made of a same material such that the optical surfaces 114 and the bond pads 116 can be formed in a same process step. Respective sets of bond pads 116 may be provided for each optical MEMS die 101a and 101b. Bond pads 116 are electrically connected to the internal MEMS device structures 110 through the device layers 106. Electrical connections for connecting the bond pads 116 to the internal MEMS device structures 110 are formed together with internal MEMS device structures 110 during manufacturing processes. The function of the bond pads 116 is to electrically connect external signals to the internal MEMS device structures 110. For example, during operation, the bond pads 116 may be used to provide actuation signals to the internal MEMS device structures 110 for actuating and driving an operation of the optical MEMS devices. For example, the actuation signals may be used to cause an optical MEMS device to rotate about one or more axes during operation.

As shown in FIG. 1B, after forming the unreleased wafer assembly 100A, as described in connection with FIG. 1A, and before opening the one or more inner cavities, as described below in connection with FIG. 1C, deep trenches 120 may be formed along the singulation lanes that delineate the plurality of optical MEMS dies in the unreleased wafer assembly 100A. The deep trenches 120 may be formed according to one or more etching processes using, for example, one or more etchants. It is important to note that the inner cavities 108 remain sealed by portions of the upper device layer 106b during the formation of the deep trenches 120. Thus, the inner cavities 108 are devoid of debris generated from the deep trenches 120 or the formation of the deep trenches 120. As described above, since only one singulation lane is shown delineating optical MEMS dies 101a and 101b, only one deep trench 120 is shown in FIG. 1B, however, there could be deep trenches 120 surrounding all sides of each optical MEMS die 101.

Each deep trench 120 may extend from the upper device layer 106b (e.g., from the upper surface 118) at least partially into the plurality of device layers 106. For example, in some cases, each deep trench 120 may only extend partially through the plurality of device layers 106. In other words, the deep trenches 120 may not extend to the insulation layer 104. Nevertheless, removing some of the device layers 106 may reduce an amount of wafer-separation particulate generated during a wafer separation process (e.g., a separation process step). For example, portions of the device layers 106 present in the singulation lane during a wafer separation process may generate conductive particulate that could be extremely detrimental to a function of the internal MEMS device structures 110. By removing at least some of the device layers 106 by the formation of the deep trenches 120 in the singulation lanes, the amount of conductive particulate generated during the wafer separation process can be reduced, thereby reducing a likelihood of conductive particulate entering the inner cavities 108 where it can come into contact with the internal MEMS device structures 110.

In addition, the deep trenches 120 may serve as particle traps for the particulates, thereby reducing, or in some cases preventing, particulates from drifting over the upper surface 118 during the wafer separation process. By reducing or preventing particulates from drifting over the upper surface 118 during the wafer separation process, a likelihood of particulate entering the inner cavities 108 is reduced. The wafer separation process is described in more detail in connection with FIG. 1F.

To form the deep trenches 120, a first etchant, to which the device layers 106 are reactive, may be used to remove a controlled portion of the device layers 106. For example, deep reactive ion etching (DRIE) may be used to form the deep trenches 120 in the device layers 106. The deep trenches 120 are formed in a way that does not open the inner cavities 108. Thus, the inner cavities 108 may remain closed during formation of the deep trenches 120. Accordingly, particulate generated when forming the deep trenches can be removed (e.g., cleaned) from the upper surface 118 without contaminating the inner cavities 108 because the inner cavities are still sealed closed. In some embodiments, the deep trenches 120 may be formed using a photolithography and etching process such that the deep trenches 120 are aligned on respective singulation lanes, away from the inner cavities 108. Thus, the internal MEMS device structures 110 are protected from particulates and other contaminants during formation of the deep trenches 120.

A depth of the deep trenches 120 may be defined by a depth-to-width ratio of the deep trenches 120. The magnitude of the depth-to-width ratio is important to ensure that the deep trenches 120 trap particulate and prevent wafer-separation particulate generated during the wafer separation process from drifting over the upper surface 118 and entering the inner cavities 108. In some implementations, each deep trench 120 has a depth-to-width ratio that is greater than 5, such that the deep trenches 120 are configured to trap particles generated during the wafer separation process. In other words, the depth-to-width ratio may be sufficiently large (e.g., greater than 5) to trap wafer-separation particulate within the deep trenches 120, and to prevent particles from escaping the deep trenches 120. The depth of each deep trench 120 is defined by a trench bottom 124.

In some implementations, each deep trench 120 may extend from the upper device layer (e.g., from the upper surface 118) fully through the plurality of device layers 106 to the insulation layer 104. Accordingly, the trench bottom 124 may be defined on the insulation layer 104. The insulation layer 104 may function as a stop layer for the etching of the device layer 106. For example, the insulation layer 104 may be non-reactive or resistant to the first etchant and the insulation layer 104 may be used to control the depth of the deep trenches 120.

Forming the deep trench 120 to the insulation layer 104 may further reduce the amount of wafer-separation particulate generated during the wafer separation process and may improve the deep trenches 120 as particle traps for the particulates. By completely removing the device layers 106 from the singulation lanes, the amount of conductive particulate that would be otherwise produced by the device layers 106 during the wafer separation process can be further reduced (or eliminated), thereby reducing a likelihood of conductive particulates entering the inner cavities 108 where they can come into contact with the internal MEMS device structures 110. In addition, forming the deep trenches 120 to the insulation layer 104 may increase the depth-to-width ratio of the deep trenches 120, thereby improving the deep trenches' ability to trap particles within the deep trenches 120 and prevent the particles from escaping the deep trenches 120 in way that they can drift over the upper surface 118 and enter the inner cavities 108.

In some implementations, each deep trench 120 may extend from the upper device layer (e.g., from the upper surface 118), through the plurality of device layers 106, and at least partially into the insulation layer 104. Accordingly, the trench bottom 124 may be defined in the insulation layer 104. Forming the deep trenches 120 may include performing a first etch with a first etchant that etches the plurality of device layers 106, and performing a second etch with a second etchant that etches the insulation layer 104. The first etchant may be different from the second etchant. For example, the second etchant may be hydrofluoric acid. Thus, the insulation layer 104 may be non-reactive or resistant to the first etchant and may function as a first stop layer for the first etch. By removing at least some of the insulation layer 104, the amount of wafer-separation particulate generated during a wafer separation process (e.g., a separation process step) can be reduced. In addition, forming the deep trenches 120 at least partially through the insulation layer 104 may increase the depth-to-width ratio of the deep trenches 120, thereby improving the deep trenches' ability to trap particles within the deep trenches 120 and prevent the particles from escaping the deep trenches 120 in way that they can drift over the upper surface 118 and enter the inner cavities 108.

In some implementations, each deep trench 120 may extend from the upper device layer (e.g., from the upper surface 118), through the plurality of device layers 106, through the insulation layer 104, to the wafer substrate 102. Thus, the wafer substrate 102 may serve as a trench bottom 124 for each deep trench 120. In other words, the wafer substrate 102 may define the trench bottoms 124 of the deep trenches 120. Forming the deep trenches 120 may include performing a first etch with the first etchant that etches the plurality of device layers 106, and performing a second etch with the second etchant that etches the insulation layer 104, with the first etchant and the second etchant being different etchants. The insulation layer 104 may be non-reactive or resistant to the first etchant and may function as a first stop layer for the first etch. The plurality of device layers 106 and the wafer substrate 102 may be non-reactive or resistant to the second etchant, and the wafer substrate 102 may function as a second stop layer for the second etch. Thus, when etching the insulation layer 104 with the second etchant, the wafer substrate 102 may be used to control the depth of the deep trenches 120 such that the trench bottoms 124 are at the wafer substrate 102.

By completely removing the device layers 106 and the insulation layer 104 from the singulation lanes, the amount of wafer-separation particulate that would be otherwise produced by the device layers 106 and the insulation layer 104 during the wafer separation process can be further reduced (or eliminated), thereby reducing a likelihood of wafer-separation particulate entering the inner cavities 108 where it can come into contact with the internal MEMS device structures 110. In addition, forming the deep trenches 120 to the wafer substrate 102 may increase the depth-to-width ratio of the deep trenches 120, thereby improving the deep trenches' ability to trap particles within the deep trenches 120 and prevent the particles from escaping the deep trenches 120 in way that they can drift over the upper surface 118 and enter the inner cavities 108.

In addition, another benefit of forming the deep trenches 120 to the wafer substrate 102 includes forming the trench bottoms 124 with enhanced optical properties, such as high optical smoothness, that enable improved lasing during a stealth dicing process step. The stealth dicing process step (e.g., a laser emission process of a stealth dicing process) described in more detail in connection with FIG. 1D. Thus, forming the trench bottoms 124 at the wafer substrate 102 may include processing the trench bottoms 124 to be optically smooth and horizontal in order to enable the laser beams emitted during the stealth dicing process step to pass through the trench bottoms 124 and into the wafer substrate 102 at a desired direction, depth, and optical power. For example, the bottom surfaces of the deep trenches 120, corresponding to the trench bottoms 124, may be processed to reduce (or prevent) optical scattering and back reflection of the laser beams emitting during a laser emission process (e.g., a laser emission process of a stealth dicing process). As a result, the trench bottoms 124 located at the wafer substrate 102 may ensure that weakened structural regions (e.g., internal modifications from stealth dicing or defect region) generated during the stealth dicing process step are vertically aligned and are formed at intended depths with the intended optical power, which enables a cleaner, smoother, more precise separation during the wafer separation process. As a result, edges of the wafer substrate 102 (e.g., edges of the optical MEMS dies 101) after the separation process step are straight and smooth. Moreover, a likelihood of cracking, breaking, and/or chipping at the edges of wafer substrate 102 (e.g., edges of the optical MEMS dies 101) is reduced, thereby increasing a yield of operable optical MEMS die.

In some examples, the second etch, extending to or partially into the wafer substrate 102, may form the trench bottoms 124 at the wafer substrate 102, which may result in the surfaces of the trench bottoms 124 being optically smooth, to reduce optical scattering of the laser beams. A reduction in optical scattering may result in improved beam focusing during laser emission, which may result in more accurate lasing of the wafer substrate 102 (e.g., more accurate formation of weakened structural regions within the wafer substrate 102) and a cleaner, smoother, more precise separation during the wafer separation process. Moreover, the reduction in optical scattering may result in fewer particles being generated during the wafer separation process. In some embodiments, the surface of the trench bottom 124 may be processed separately from (e.g., after) the steps of forming the deep trench 120 to improve optical performance of a laser beam (e.g., the one or more laser beams) through the surface.

In addition, each deep trench 120 may have a trench width that is greater than a laser beam width of the laser beams to ensure that the device layers 106 do not interfere with the laser beams. Interfering with the device layers 106 may cause scattering, clipping, focal point deviations, nonuniform beam power, and/or other non-uniformities in the laser beams that may negatively impact an accuracy of forming weakened structural regions within the wafer substrate 102 during the laser emission process of the stealth dicing process step. Interfering with the device layers 106 may cause the weakened structural regions to be vertically misaligned, located incorrect depths, and/or not sufficiently weak, which may lead to cracking, breaking, and/or chipping at the edges of wafer substrate 102 during the separation process step and a reduced manufacturing yield.

In addition, as a result of the etching process(es) used for forming the deep trenches 120, trench sidewalls of the deep trenches 120 may have structures with horizontal surface patterns. For example, the structures may extend horizontally along a y-axis. The trench sidewall surface patterns from etching are orders or magnitude larger than the internal modifications formed in the wafer substrate 102 from stealth dicing. The deep trenches 120 are formed without forming weakened structural regions in the plurality of device layers 106. For example, after forming the deep trenches 120, the plurality of device layers 106 may be devoid of weakened structural regions, such as microcracks, delamination, thermal stress damage, localized phase changes, phase transitions, fracture planes, and/or subsurface defects.

After forming the deep trenches 120, and prior to releasing the unreleased wafer assembly, any particulate accumulated on the upper device layer 106b may be cleaned away, thereby preventing the particulate from contaminating upper device layer structures and/or entering the inner cavities 108.

As shown in FIG. 1C, after forming deep trenches 120, as described in connection with FIG. 1B, a released wafer assembly 100B may be formed by unsealing the upper device layer 106b, thereby opening the one or more inner cavities 108 of the unreleased wafer assembly 100A to form a plurality of optical MEMS devices 126 (e.g., optical MEMS devices 126a and 126b) in the plurality of device layers 106. The optical MEMS devices 126 are MEMS mirror devices that include a mechanical moving mirror (e.g., MEMS mirror body 112) integrated on an optical MEMS die 101.

Unsealing the upper device layer 106b may include etching the upper device layer 106b to form openings 128 that extend from the upper surface 118 into the inner cavities 108. The etching typically does not generate particulate. Therefore, the openings 128 may be formed with little risk to particulate entering the inner cavities.

The openings 128 are formed to define the MEMS mirror bodies 112 of the plurality of optical MEMS devices 126 and to release the MEMS mirror bodies 112 from the upper device layer 106b of the optical MEMS dies 101. In particular, releasing the MEMS mirror bodies 112 from the upper device layer 106b includes releasing (e.g., separating) the MEMS mirror bodies 112 from the frames 113 to enable the MEMS mirror bodies 112 to rotate about one or more axes.

The openings 128 are also formed to define a suspension system in the upper device layer 106b. The suspension system includes suspension structures 129 that attach each MEMS mirror body 112 to a respective frame 113 and suspend each MEMS mirror body 112 over a respective inner cavity 108. For example, a set of suspension structures 129 attach each MEMS mirror body 112 to a respective frame 113 that is rotationally fixed. The set of suspension structures 129, such as torsion beams, linkages, or hinges, enable rotation of the MEMS mirror body 112 about one or more axes of rotation. Thus, unsealing the upper device layer 106b includes forming the openings 128 through the upper device layer 106b to each respective inner cavity 108 in order to release each MEMS mirror body 112 and enable a MEMS function of each optical MEMS device 126.

Each MEMS mirror body 112 may be attached to a frame 113 by a pair of oppositely arranged suspension structures 129. In the example shown in FIG. 1C, the suspension structures 129 extend along the y-axis (e.g., into and out of the drawing sheet). A respective pair of suspension structures 129 may extend, at least partially, along a corresponding axis of rotation. For example, another pair of suspension structures may extend along the x-axis. Thus, even though the openings 128 release the MEMS mirror bodies 112 from the frames 113 to enable rotational movement about one or more axes, the MEMS mirror bodies 112 remain attached to the frames 113 by suspension structures 129.

While forming the openings 128 enables the MEMS function of each optical MEMS device 126, the openings 128 expose the inner cavities 108 to an external environment. As a result, it is critical to the operation of the optical MEMS devices 126 to prevent particulate from entering the inner cavities 108 after unsealing the upper device layer 106b, where the particulate can come into contact with the internal MEMS device structures 110.

As shown in FIG. 1D, after forming the released wafer assembly 100B, as described in connection with FIG. 1C, laser beams may be emitted, along the singulation lanes, into one or more layers located below the trench bottoms 124 of the deep trenches 120. The laser beams are used to defect regions 130 within the one or more layers located below the trench bottoms 124. The defect regions 130 are weakened structural regions that enable the optical MEMS dies 101 to be separated during the separation process step. Thus, a laser emission process (such as of a stealth dicing process) may be performed.

In some examples, the trench bottoms 124 are arranged at the wafer substrate 102 and the laser beams are focused at different depths of the wafer substrate 102 to form the defect regions 130 at different depths within the wafer substrate 102. The defect regions 130 are laser-induced modifications internal to the wafer substrate 102. For example, each laser beam may create, along a respective singulation lane, a modified region within the wafer substrate 102 (or other layers below the trench bottoms 124) with weakened structure aspects. Thus, the defect regions 130 are weakened structural regions at which the wafer is to be separated to form separate dies. The defect regions 130 may include aligned structures, internal to the released wafer assembly 100B. The aligned structures may include at least one of microcracks, delamination, thermal stress damage, localized phase changes, phase transitions, fracture planes, or subsurface defects that enable the dies to be separated along a defined delineation corresponding to a singulation lane.

As shown in FIG. 1E, a plurality of defect regions 130 may be formed at different depths by focusing laser beams at different depths within the released wafer assembly 100B. The defect regions 130 may be aligned vertically along a defined delineation corresponding to the singulation lane. Accordingly, a wafer 100C is formed. The wafer 100C may be a modified released wafer assembly, similar to released wafer assembly 100B, except with defect regions 130. The wafer 100C includes a substrate (e.g., wafer substrate 102), the insulation layer 104 arranged on the substrate, and the plurality of device layers 106 arranged on the insulation layer 104. The wafer 100C includes deep trenches 120, extending into the wafer 100C from the upper device layer 106b of the plurality of device layers 106, delineating a set of dies (e.g., optical MEMS dies 101a and 101b) in the wafer 100C, the deep trenches 120 having trench bottoms 124 (e.g., bottom surfaces). The deep trenches 120 may have sidewalls 122 with structures having horizontal surface patterns produced during the formation of the deep trenches 120.

Defect regions 130, located below the trench bottoms 124 of the deep trenches 120, include aligned structural weaknesses. For example, the defect regions 130 may be located within an internal volume of the wafer substrate 102 and/or other layers below the trench bottoms 124 of the deep trenches 120. The aligned structural weaknesses may be vertically aligned. The deep trenches 120 help to ensure that the defect regions 130 are vertically aligned along the intended singulation lanes. For example, the trench bottoms 124 may reduce optical scattering of the laser beams, ensuring that the defect regions 130 are vertically aligned and are formed at the intended depths. The aligned structural weaknesses may include at least one of microcracks, delamination, thermal stress damage, localized phase changes, phase transitions, fracture planes, or subsurface defects resultant from the laser beams. In other words, the aligned structural weaknesses are laser-induced modifications internal to the wafer 100C (e.g., internal to the wafer substrate 102 and/or other layers below the trench bottoms 124 of the deep trenches 120).

Each optical MEMS die 101 has an optical MEMS surface (e.g., optical surface 114) and one or more inner cavities 108 arranged below the optical MEMS surface. The upper device layer 106b includes openings 128 into the one or more inner cavities 108. The trench bottoms 124 of the deep trenches 120 may be optically smooth or otherwise processed, to reduce optical scattering and back reflection.

Above the trench bottoms 124 of the deep trenches 120, the wafer 100C is devoid of weakened structural regions. For example, external edges of the device layers 106 are devoid of weakened structural regions. In addition, the inner cavities 108 are devoid of debris, such as particulate, from the deep trenches 120, due to the upper device layer 106b being sealed during the formation of the deep trenches 120, as described in connection with FIG. 1B.

As shown in FIG. 1F, after emitting the one or more laser beams, as described in connection with FIGS. 1D and 1E, the wafer 100C (e.g., the modified released wafer assembly) may be separated, through the defect regions 130, into the plurality of optical MEMS dies 101a and 101b. For example, the wafer 100C may be separated using a wafer separation process that includes applying an external force, such as expanding the wafer substrate 102 by stretching tape applied under the wafer substrate 102. The external force may cause the wafer 100C to break cleanly along weakened singulation lanes. The defect regions 130 may act as stress points, guiding the breakage through the intended singulation lanes, ensuring that the optical MEMS dies 101a and 101b are cleanly separated without damaging the optical MEMS dies 101a and 101b.

Though the amount of particulate produced during the wafer separation process may be reduced based on the formation of the deep trench 120, some particulates are still generated during the wafer separation process as the optical MEMS dies 101 are pulled apart. The deep trench 120 serves as a particle trap during the wafer separation process, thereby preventing particulates from entering the inner cavities 108 (e.g., through openings 128), where the internal MEMS device structures 110 reside. For example, the deep trenches 120 have a depth-to-width ratio sufficient for trapping particulates and preventing particulates from escaping the deep trenches 120 where they may land on the upper surface 118 and/or enter the inner cavities 108 of the wafer 110C. Thus, the deep trenches 120 significantly reduce a likelihood that one or more particulates will enter the inner cavities 108. As a result, the deep trenches 120 protect the internal MEMS device structures 110, including the actuation structures, from particulate contamination, thereby preventing operational errors and damage, and improving the reliability of the optical MEMS dies 101.

After singulation (e.g., after being separated), sidewalls of the optical MEMS dies 101a and 101b below the trench bottoms 124 of the deep trenches 120 and corresponding to the defect regions 130 (e.g., regions that were modified by the laser beams) may have vertical surface patterns. For example, sidewalls of the optical MEMS dies 101 and 101b below the trench bottoms 124 of the deep trenches 120 may have structures with vertical surface patterns that extend along a z-axis.

In addition, after singulation, the trench bottoms 124 are split between adjacent optical MEMS dies 101 and become a shelf at the periphery of each optical MEMS die 101. A shelf extends around an outside of an optical MEMS die 101, and delineates a change in a cross-sectional width of the optical MEMS die 101. For example, above the shelf, the optical MEMS die 101 has a first cross-sectional width, and, below the shelf, the optical MEMS die 101 has a second cross-sectional width that is larger than the first cross-sectional width. The shelf may be optically smooth to reduce optical scattering and back reflection such that the shelf is configured to enable a laser beam to pass through the shelf and into the wafer substrate 102 at a desired direction, depth, and optical power.

As indicated above, FIGS. 1A-1F are provided as examples. Other examples may differ from what is described with regard to FIGS. 1A-1F. For example, while the examples are directed to optical MEMS wafers and dies, the method of manufacturing described in connection with FIGS. 1A-1F may be applicable to other types of MEMS wafers and dies having one or more inner cavities in which particle-sensitive components are arranged and are to be protected from particles during manufacturing.

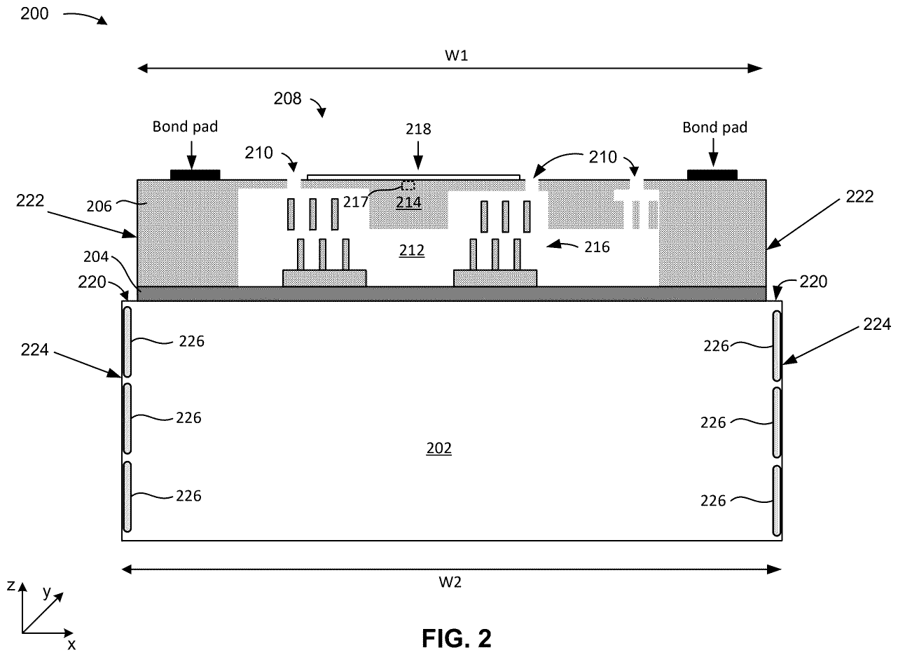

FIG. 2 shows a cross-section of an optical MEMS die 200 according to one or more implementations. The optical MEMS die 200 may correspond to optical MEMS die 101a or optical MEMS die 101b after the wafer separation process described in connection with FIG. 1F. In other words, the optical MEMS die 200 may be manufactured using the method of manufacturing described in connection with FIGS. 1A-1F.

The optical MEMS die 200 may include a substrate 202, an insulation layer 204 arranged on the substrate 202, and a plurality of device layers 206 arranged on the insulation layer 204. The substrate 202, the insulation layer 204, and the plurality of device layers 206 may correspond to the wafer substrate 102, the insulation layer 104, and the plurality of device layers 106 described above in connection with FIGS. 1A-1F. In addition, the optical MEMS die 200 includes an optical MEMS device 208 having openings 210 into one or more cavities 212 defined within the plurality of device layers 206.

The optical MEMS device 208 includes a MEMS mirror body 214 formed in an upper device layer of the device layers 206, and internal MEMS device structures 216 arranged within a cavity 212. The internal MEMS device structures 216 include actuation structures that are highly sensitive to particulate contamination. The actuation structures are used to drive the MEMS mirror body 214 about one or more axes of rotation. The cavities 212 may be free of particulate contamination based on the optical MEMS die 200 being manufactured with the processes described in connection with FIGS. 1A-1F. As a result, the internal MEMS device structures 216 may operate in a reliable manner, unaffected by particulate contamination.

Suspension structures 217 mechanically attach the MEMS mirror body 214 to a frame portion 218 of the device layers 206 to suspend the MEMS mirror body 214 over a cavity 212. The suspension structures 217 also enable rotation of the MEMS mirror body 214 about the one or more axes of rotation. An optical surface 219 may be arranged on the MEMS mirror body 214 to form a MEMS mirror. The MEMS mirror body 214 and the optical surface 219 may be arranged between respective openings of the openings 210 into the one or more cavities 212. The openings 210 enable a MEMS function of the optical MEMS device 208, as described above in connection with FIG. 1C.

The optical MEMS die 200 may include a shelf 220 that extends around an outside or periphery of the optical MEMS die 200. In some examples, the shelf 220 may extend around an entire periphery of the optical MEMS die 200. Thus, the shelf 220 may extend around all sides of the optical MEMS die 200. The shelf 220 may be provided in one of the device layers 206, the insulation layer 204, or the substrate 202, at a at a predefined depth of the optical MEMS die 200. For example, the shelf 220 may correspond to a trench bottom of one or more trenches (e.g., trench bottoms 124 of deep trenches 120). For example, the shelf 220 may correspond to a portion of the trench bottoms 124 of the deep trenches 120 described in connection with FIGS. 1B-1F. In other words, the shelf 220 may include bottoms of a set of one or more trenches. In addition, the shelf 220 may be optically smooth or processed to reduce optical scattering and back reflection.

In some examples, the shelf 220, corresponding to the bottoms of one or more deep trenches 120, may be formed at an upper surface of the substrate 202. The shelf 220 may be processed to be optically smooth and horizontal to reduce optical scattering of the laser beams that are transmitted through the upper surface of the shelf 220 (e.g., through the substrate 202) and into the substrate 202 during a laser emission process of a stealth dicing process. The horizontal, smooth, and/or processed surface of the shelf 220 may ensure that the laser beams are not deflected in unintended directions as the laser beams are transmitted through the shelf 220. Thus, the shelf 220 may be optimized for optical transmission such that laser beams pass through the shelf 220 into the substrate 202 at a desired direction, depth, and optical power. For example, the shelf 220 has an optically smooth surface configured to reduce optical scattering and back reflection of one or more laser beams. The shelf 220 is configured to receive a laser beam at the optically smooth surface, and the optically smooth surface is configured to enable the laser beam to pass through the shelf 220 and into the substrate 202 at a desired (target) direction, depth, and optical power. In some examples, the optically smooth surface is the upper surface of the substrate 202.

A reduction in optical scattering at the shelf 220 results in improved beam focusing into the substrate 202 during laser emission, which results in more accurate lasing of the substrate 202 (e.g., more accurate formation of weakened structural regions within the substrate 202) and a cleaner, smoother, more precise separation during the wafer separation process. For example, a reduction in optical scattering at the shelf 220 may ensure that the defect regions 130 are vertically aligned and are formed at the intended depths, which enables a cleaner, smoother, more precise separation during the wafer separation process. As a result, edges of the substrate 202 are straight and smooth.

The shelf 220 delineates a change in a cross-sectional width of the optical MEMS die 200. For example, the optical MEMS die 200 has a first cross-sectional width W1 above the shelf 220 (e.g., between a top surface of the optical MEMS die 200 and the shelf 220), and has a second cross-sectional width W2 below the shelf 220 (e.g., between a bottom surface of the optical MEMS die 200 and the shelf 220). Thus, the cross-sectional width of the optical MEMS die 200 changes from the first cross-sectional width W1 to the second cross-sectional width W2 at the shelf 220. Accordingly, the shelf 220 provides a stepped transition between the first cross-sectional width W1 to the second cross-sectional width W2. For example, in the case that the shelf 220 is located at the upper surface of the substrate 202, the insulation layer 204 and the plurality of device layers 206 may have the first cross-sectional width W1, and the substrate 202 may have the second cross-sectional width W2. Thus, the shelf 220 is arranged at a predefined depth of the optical MEMS die 200, the shelf 220 being arranged at a device layer (e.g., in one of the device layers 106), at an insulation layer (e.g., in one of the insulation layers 204), or at the substrate 202. In addition, a difference between the second cross-sectional width W2 and the first cross-sectional width W1 (e.g., W2−W1) is greater than the stealth dicing laser beam width in order to ensure that the sidewalls above the shelf 220 do not interfere with laser beams emitted during a laser emission process of a stealth dicing process. The predefined depth, at which the shelf 220 is arranged from the top surface of the optical MEMS die 200, may be greater than five times a difference between the second cross-sectional width and the first cross-sectional width (e.g., shelf depth>5×(W2−W1)). Accordingly, the section of the optical MEMS die 200 above the shelf 220 may be designed to trap particulates originating from edges of the die 220 below the shelf 220, and prevent the particulates from drifting over the top surface of the optical MEMS die 200. As a result, the predefined depth at which the shelf 220 is arranged can prevent the particulate from entering the inner cavities 212 where the internal MEMS device structures 216 reside.

The optical MEMS die 200 may have first sidewalls 222 and second sidewalls 224. The first sidewalls 222 may be arranged above the shelf 220, extending between the 220 shelf and a top surface of the plurality of device layers 206. The second sidewalls 224 may be arranged below the shelf 220, extending between the shelf 220 and a bottom surface of the substrate 202. The first sidewalls 222 may be formed by one or more trenches (e.g., deep trenches 120). In other words, the first sidewalls 222 may be produced by the processes used to form the deep trenches 120 described in connection with FIG. 1B. For example, the first sidewalls 222 may be produced according to an etching process. Thus, the first sidewalls 222 may correspond to trench sidewalls of the deep trenches 120. As a result, the first sidewalls 222 may have structures with horizontal surface patterns. The structures of the first sidewalls 222 may be formed in a horizontal surface pattern (e.g. scalloped). For example, the horizontal surface pattern may include a plurality of scallops that are arranged vertically along a first sidewall 222 in a vertical direction (e.g., along the z-axis), with each scallop arranged at a respective vertical depth along the first sidewall 222. Each scallop may be a structure of the horizontal surface pattern that extends horizontally across a first sidewall 222, parallel to the y-axis. The shape and size of the structures of the horizontal surface pattern may be determined by the particular etching process applied to form the deep trenches 120. In some examples, the horizontal surface patterns may correspond to iterations of photolithographic or etching processes.

The second sidewalls 224 may be formed by the laser emission process, as described in connection with FIGS. 1D and 1E, and the wafer separation process, described in connection with FIG. 1F. In some implementations, the second sidewalls 224 may be formed by a stealth dicing process. Thus, the second sidewalls 224 may correspond to stealth dicing sidewalls. As a result, the second sidewalls 224 may have structures forming vertical surface patterns. The structures of the second sidewalls 224 may be vertically-oriented internal modifications or weakened structural regions (e.g., striations). Thus, the structures of the second sidewalls 224 may be arranged horizontally along a second sidewall 224 in a horizontal direction (e.g., along the y-axis), with each structure arranged at a respective lateral position along the second sidewall 224. Each structure of the vertical surface pattern extends vertically across a portion the second sidewall 224, parallel to the z-axis. The shape and size of the structures of the vertical surface pattern may be determined by the process applied to form internal modifications or weakened structural regions and separate the die. In some examples, the vertical surface patterns may correspond to iterations of a stealth dicing process. In addition, the optical MEMS die 200 may have weakened structural regions 226 below the shelf 220 and proximate to the outside of the optical MEMS die 200 (e.g. proximate to the second sidewalls 224). The weakened structural regions 226 correspond to the defect regions 130 (e.g., internal modifications) formed by one or more laser beams during the laser emission process. The weakened structural regions 226 may be formed as described in connection with FIGS. 1D and 1E. The weakened structural regions 226 may be laser-induced modifications internal to the optical MEMS die 200 (e.g., internal to the substrate 202). For example, the weakened structural regions 226 may be sub-surface regions located within the substrate 202, and remain after the wafer separation process described in connection with FIG. 1F.

The weakened structural regions 226 may include aligned structures, internal to the optical MEMS die 200. The aligned structures may include at least one of microcracks, delamination, thermal stress damage, localized phase changes, phase transitions, fracture planes, or subsurface defects. As with the internal modifications, the shape and size of the weakened structural regions may be determined by the process applied. Thus, in some embodiments, while the optical MEMS die 200 includes weakened structural regions 226 below the shelf 220, the optical MEMS die 200 is devoid of the same weakened structural regions 226 above the shelf 220. In other words, above the shelf 220, the optical MEMS die 200 is devoid of weakened structural regions and devoid of structures that are characteristically similar to the weakened structural regions arranged below the shelf 220. For example, if the shelf is on the substrate 202, the insulation layer 204 and the device layers 206 may be devoid of weakened structural regions 226. In this context, “Characteristically similar” means characteristics indicative of laser-induced modifications that would be similar in size, width, length, and structure to the weakened structural regions arranged below the shelf 220.

Accordingly, when considering a die 200, the sidewalls 222 above the shelf 220 and the sidewalls 224 below the shelf 220 have different surface patterns: structures forming a horizontal pattern above the shelf 220 and other structures forming a vertical pattern below the shelf 220. Furthermore, a size (e.g., repetition period) of these patterns may be different. A vertical repetition period of the horizontal surface pattern may correspond to a vertical dimension of the scallops on the first sidewall 222, for example, 100 to 500 nm. Concurrently, a horizontal repetition period of the vertical surface pattern may correspond to a horizontal spacing between weakened structural regions (or internal modification) on (or in) the second sidewall 224, for example 1 to 3 um (1000 to 3000 nm). Generally, the horizontal surface patterns may have a repetition rate that is at least an order of magnitude smaller than the repetition rate of the vertical surface patterns.

As indicated above, FIG. 2 is provided as an example. Other examples may differ from what is described in connection with FIG. 2.

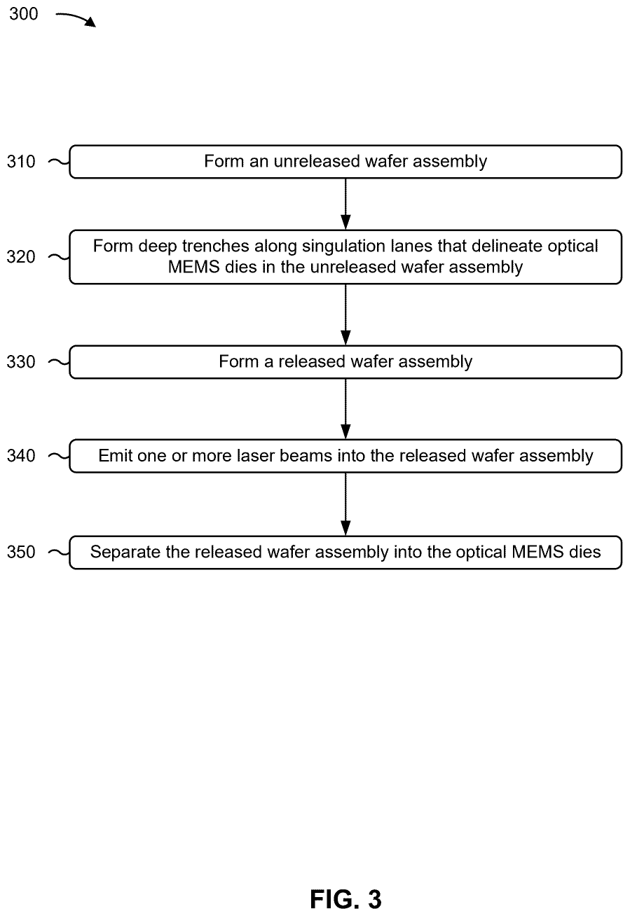

FIG. 3 is a flowchart of an example process 300 associated with forming deep trenches on microelectromechanical system wafers for stealth dicing. In some implementations, one or more process blocks of FIG. 3 are performed by a manufacturing system for producing a plurality of dies (e.g., optical MEMS dies). The manufacturing system may implement various semiconductor manufacturing processes, as described elsewhere herein, for producing the plurality of dies.

As shown in FIG. 3, process 300 may include forming an unreleased wafer assembly (block 310). For example, the unreleased wafer assembly may be formed as similarly described in connection with FIG. 1A.

As further shown in FIG. 3, process 300 may include forming deep trenches along singulation lanes that delineate optical MEMS dies in the unreleased wafer assembly (block 320). For example, the deep trenches may be formed as similarly described in connection with FIG. 1B.

As further shown in FIG. 3, process 300 may include forming a released wafer assembly (block 330). For example, the released wafer assembly may be formed as similarly described in connection with FIG. 1C.

As further shown in FIG. 3, process 300 may include emitting one or more laser beams into the released wafer assembly (block 340). For example, the one or more laser beams may be emitted as similarly described in connection with FIGS. 1D and 1E.

As further shown in FIG. 3, process 300 may include separating the released wafer assembly into the optical MEMS dies (block 350). For example, the released wafer assembly may be separated into the optical MEMS dies as similarly described in connection with FIG. 1F.

Process 300 may include additional implementations, such as any single implementation or any combination of implementations described below and/or in connection with one or more other processes described elsewhere herein.

Although FIG. 3 shows example blocks of process 300, in some implementations, process 300 includes additional blocks, fewer blocks, different blocks, or differently arranged blocks than those depicted in FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A die, comprising:
a substrate;
an insulation layer arranged on the substrate;
a device layer arranged on the insulation layer, wherein a microelectromechanical systems (MEMS) device, having openings into one or more inner cavities, is defined within the device layer;
a shelf arranged around an outside of the die,
wherein the shelf delineates a change in a cross-sectional width of the die, and
wherein the shelf is arranged at a predefined depth of the die, the shelf being arranged at the device layer, at the insulation layer, or at the substrate; and
weakened structural regions arranged below the shelf and proximate to the outside of the die.

2. The die of claim 1, wherein the shelf extends around all sides of the die.

3. The die of claim 1, wherein the shelf comprises bottoms of a set of one or more trenches.

4. The die of claim 1, wherein the shelf is arranged at the substrate, and
wherein the shelf is smooth to reduce optical scattering such that the shelf is configured to enable a laser beam to pass through the shelf and into the substrate to form the weakened structural regions.

5. The die of claim 1, wherein the shelf has an optically smooth surface configured to reduce optical scattering of a laser beam.

6. The die of claim 1, wherein, above the shelf, the die is devoid of structures that are characteristically similar to the weakened structural regions arranged below the shelf.

7. The die of claim 1, wherein the weakened structural regions comprise aligned structures, internal to the die, and
wherein the aligned structures comprise at least one of microcracks, delamination, thermal stress damage, localized phase changes, phase transitions, fracture planes, subsurface defects, or laser-induced modifications.

8. The die of claim 1, further comprising:
first sidewalls extending between the shelf and a top surface of the die, wherein the first sidewalls have structures with horizontal surface patterns; and
second sidewalls extending between the shelf and a bottom surface of the die, wherein the second sidewalls have structures with vertical surface patterns.

9. The die of claim 8, wherein the first sidewalls are devoid of structures that are characteristically similar to the weakened structural regions arranged below the shelf, and
wherein the weakened structural regions arranged below the shelf are arranged at or proximate to the second sidewalls.

10. The die of claim 1, wherein, above the shelf, between a top surface of the die and the shelf, the die has a first cross-sectional width,
wherein, below the shelf, between a bottom surface of the die and the shelf, the die has a second cross-sectional width that is larger than the first cross-sectional width, and
wherein the predefined depth, at which the shelf is arranged from the top surface of the die, is greater than five times a difference between the second cross-sectional width and the first cross-sectional width.

11. The die of claim 1, further comprising:
suspension structures,
wherein the MEMS device includes a mirror arranged on the device layer, and
wherein the suspension structures suspend the mirror over an inner cavity of the one or more inner cavities.

12. A wafer, comprising:
a substrate;
an insulation layer arranged on the substrate;
a plurality of device layers arranged on the insulation layer, the plurality of device layers including an upper device layer;
trenches extending into the wafer from the upper device layer and delineating a set of dies in the wafer, the trenches having trench bottoms; and
regions, arranged below the bottoms of the trenches, comprising aligned structural weaknesses,
wherein each die of the set of dies having an optical microelectromechanical systems (MEMS) surface in the upper device layer and one or more inner cavities below the optical MEMS surface.

13. The wafer of claim 12, wherein the trenches are configured to trap particles originating from a portion of the wafer arranged below the trench bottoms.

14. The wafer of claim 12, wherein the trench bottoms are optically smooth to reduce optical scattering such that the trench bottoms are configured to enable a one or more laser beams to pass through the trench bottoms and into the substrate at a desired direction, depth, and optical power.

15. The wafer of claim 12, wherein trench sidewalls of the trenches are devoid of weakened structural regions.

16. The wafer of claim 12, wherein the aligned structural weaknesses comprise at least one of microcracks, delamination, thermal stress damage, localized phase changes, phase transitions, fracture planes, or subsurface defects.

17. The wafer of claim 12, wherein the aligned structural weaknesses are laser-induced modifications internal to the wafer.

18. The wafer of claim 12, wherein the trenches have sidewalls with structures having horizontal surface patterns, and
wherein the aligned structural weaknesses are vertically aligned.

19. A method of manufacturing a plurality of optical microelectromechanical systems (MEMS) dies, the method comprising:
forming an unreleased wafer assembly including a wafer substrate, an insulation layer formed on the wafer substrate, and a plurality of device layers formed on the insulation layer,
wherein the plurality of device layers includes an upper device layer and one or more inner cavities,
wherein the one or more inner cavities contain MEMS actuation structures that are sensitive to particulate, and
wherein the upper device layer of the plurality of device layers is sealed such that the one or more inner cavities are closed;
after forming the unreleased wafer assembly and before opening the one or more inner cavities, forming deep trenches along singulation lanes that delineate the optical MEMS dies in the unreleased wafer assembly,
wherein each deep trench extends from the upper device layer to a depth that is at least partially into the plurality of device layers;
after forming deep trenches, forming a released wafer assembly by unsealing the upper device layer thereby opening the one or more inner cavities of the unreleased wafer assembly to form a plurality of optical MEMS devices in the plurality of device layers;
after forming the released wafer assembly, emitting one or more laser beams into the wafer substrate to create defect regions within the singulation lanes of the wafer substrate; and
after emitting the one or more laser beams, separating the released wafer assembly, through the defect regions in the wafer substrate, into the plurality of optical MEMS dies.

20. The method of claim 19, wherein unsealing the upper device layer includes etching the upper device layer to define mirror bodies of the plurality of optical MEMS devices, thereby opening the one or more inner cavities of the unreleased wafer assembly and releasing the mirror bodies from the upper device layer.

21. The method of claim 19, wherein each deep trench has a depth-to-width ratio that is greater than 5.

22. The method of claim 19, wherein each deep trench has a trench width that is greater than a laser beam width of the one or more laser beams.

23. The method of claim 19, wherein each optical MEMS device of the plurality of optical MEMS devices includes a MEMS mirror body arranged over a respective inner cavity of the one or more inner cavities, and
wherein unsealing the upper device layer includes forming a plurality of openings through the upper device layer to each respective inner cavity in order to release each MEMS mirror body and enable a MEMS function of each optical MEMS device.

24. The method of claim 19, wherein each deep trench extends from the upper device layer and through the plurality of device layers,
wherein forming the deep trenches comprises:
performing a first etch with a first etchant that etches the plurality of device layers; and
performing a second etch with a second etchant that etches at least partially into the insulation layer or through the insulation layer and at least partially into the substrate,
wherein the first etchant is different from the second etchant, and
wherein the insulation layer a stop layer for the first etch.

25. The method of claim 19, wherein forming the deep trenches includes forming bottom surfaces of the deep trenches to reduce scattering of the one or more laser beams during emitting of the one or more laser beams.
